(19) United States
(12) Patent Application Publication
(10) Pub. No.: US 2008/0180150 A1
(43) Pub. Date: Jul. 31, 2008

(54) Digital circuit semiconductor device, and clock adjusting method

(76) Inventor: Kazuhiro Yamamoto, Tokyo (JP)

Correspondence Address: MURAMATSU & ASSOCIATES, Suite 310, 114 Pacifica, Irvine, CA, 92618, US

(21) Appl. No.: 11/519,401

(22) Filed: Sep. 11, 2006

(30) Foreign Application Priority Data
Sep. 14, 2005 (JP) 2005-267234

(51) Int. Cl. H03L 7/00

(52) U.S. Cl. 327/161

(57) ABSTRACT

A low-speed general-purpose inspection apparatus is used to automatically adjust a variable delay circuit and compensate for a delay variation in order to enable an inspection and to achieve a reduction in cost and an improvement in an inspection quality.

A digital circuit 10a is provided with clock operation circuits which output data signals in accordance with input timing of a clock signal, and the digital circuit 10a comprises: variable delay circuits 13-1 and 13-2 which give predetermined delay times to the clock signal or the data signals; a delay circuit 14a having a delay time corresponding to a predetermined multiple of the cycle of a test signal; and a data maintaining circuit which compares the delay time of the delay circuit 14a with the time corresponding to the predetermined multiple of the cycle of the test signal to judge whether the delay variation of the data signals is faster or slower than a predetermined time, and compensates for the delay times of the variable delay circuits 13-1 and 13-2 on the basis of the result of the judgment.

### BACKGROUND OF THE INVENTION

1. Field of the Invention

The present invention relates to a digital circuit comprising one or more clock operation circuits (e.g., flip flops) which perform predetermined operations on the basis of an input of a clock signal, to a semiconductor device in which the digital circuit is installed, and to a clock adjusting method for the digital circuit. More particularly, it relates to a digital circuit, a semiconductor device and a clock adjusting method which are suitable for using a general-purpose low-speed test apparatus to compensate for a delay variation between clock operation circuits in the digital circuit in order to achieve an improvement in an inspection quality as well as a reduction in cost.

2. Description of the Related Art

In general, for an LSI composed of a large number of circuit elements, a computer-aided design (CAD) method is used to design a specific circuit structure. In a development process using this CAD, abstract circuit data corresponding to a function of the LSI targeted for development is defined by a hardware description language on the basis of a decided specification, and logic synthesis and the like are further carried out to generate a logic circuit, thus deciding the specific circuit structure to be installed on a chip.

The LSI manufactured through such a design process performs verification operations on a logical level and an actual operation level in a step of a manufacturing process. For example, at a wafer-level stage, logical verification is conducted by a low-speed inspection apparatus to eliminate defective products, and at the stage where the packaging of chips is finished, an actual operation is verified, so that those judged as nondefective are only shipped as products.

The manufacturing process of such an LSI will be described referring to FIG. 8.

As shown in FIG. 8, the manufacturing process of the LSI generally passes through an LSI designing stage, an LSI process stage and an LSI assembly and inspection stage.

At the LSI designing stage, the CAD is generally used to conduct function designing, logical designing, circuit designing, layout designing, etc.

At the LSI process stage, the LSI is actually manufactured, and mask production, wafer manufacture (single crystal manufacture, machining, wrapping, polishing, etc.), wafer treatments (thin film formation, oxidation, doping, annealing, etching, etc.) and others are carried out.

At the LSI assembly and inspection stage, wafer probing (wafer test), mounting/assembly, a final test, board mounting, initialization, etc. are carried out.

In the wafer probing among the above, the LSIs created within a wafer are automatically inspected one by one in a wafer state. In this inspection, an inspection needle (probe) is put on the wafer, and a test signal with a predetermined frequency is transmitted and received between the probe and the LSI.

In the mounting/assembly, the following processing is carried out: dicing processing for dividing the wafer into LSI chips; bonding processing for connecting an electrode on the surface of the chip to a terminal of a lead frame with a gold wire; molding processing (packaging) for completely sealing the LSI chip into a plastic resin; etc.

In the final test, various automatic inspection apparatuses (testers) are used to verify the actual operation with regard to the LSI after mounted in order to find whether electric properties, reliability, etc. are secured. Then, those judged as nondefective are only shipped as products.

In the board mounting, the packaged LSI is mounted on a substrate (board) made of, for example, epoxy.

In the initialization, values of circuits installed on the LSI are initialized.

Meanwhile, a large number of LSIs are created on one wafer, but not all of them have satisfactory characteristics. For example, at the stage where designed circuits are actually formed on a semiconductor substrate, it is not easy to completely reproduce the electric properties of the designed circuit structure due to a delay variation based on the process, voltage and temperature, and a difference of characteristics may be made between the designed circuit and the mounted circuit.

Such a characteristic difference is not regarded as a practical problem if it is small, but, for example, in parts which operate at a high speed, the operation can be obstructed by a difference of delay times resulting from a slight difference of film thickness.

On the contrary, a designing approach has been proposed, wherein a variable delay circuit is used to enable a delay amount to be passed after the initialization with regard to a critical path in which data can not be passed between flip flops when all variation ranges are considered (e.g., refer to Patent document 1).

According to this proposal, as shown in FIG. 9, in a digital circuit 100 in which a plurality of circuits (clock operation circuits 111-1 and 111-2 in FIG. 9) operating synchronously with input clock signals are in a connected relation, a plurality of variable delay circuits 113-1 and 113-2 which permit delay times to be variably set are inserted on an input signal line of the clock signal for the plurality of clock operation circuits. Then, the delay times of the plurality of variable delay circuits 113-1 and 113-2 are variably set to compensate for a phase lag of the clock signals.

Thus, the phases of the clock signals constituting the digital circuit can be adjusted to be the same in all the circuits or adjusted to timing on a predetermined level by the delay amount of delay elements regardless of, for example, the slight difference of film thickness.

[Patent document 1] Japanese Patent Publication Laid-open No. 2000-285144

However, in the proposal described above (clock signal adjusting method described in Patent document 1), the delay times are adjusted in the initialization during the actual operation. Therefore, the flip flop can operate at, for example, 1066 MHz after the adjustment, but there has not been delay setting which enables the flip flop to pass in a fixed pattern during inspection in all the delay variations.

Furthermore, in the proposal described above, the optimal delay time is searched by, for example, an all search method, a random search method, dynamic programming (DP), a genetic algorithm (GA) search method or a search method using CAD information. However, these methods are suitable for a case where adjustment is made with a clock signal having the same frequency as that in the actual operation during the initialization after the board mounting. Thus, in the wafer probing for inspecting with a low-speed signal, this inspection method has been improper because it is not possible due to a low clock frequency to judge whether an adjustment can be made.

Consequently, LSIs are installed which could have been eliminated as defective products if properly inspected, and there has been the necessity of replacing the LSIs which are judged as defective by the initialization and which are installed on the board. If these LSIs are properly inspected before installed on the board, it is not necessary to produce extra tasks of exchanging the LSIs and the initialization.

Furthermore, it is not necessary to spend wasteful packaging costs if the defective LSIs can be detected in the wafer probing rather than in the final test.

However, since the probe does not permit the passage of a high-speed signal in the wafer probing conducted at the wafer stage, the inspection with the low-speed signal has been forced as described above. There has thus been a desire for an inspection technique which makes it possible to judge the delay variation using a low-speed general-purpose inspection apparatus.

Moreover, the LSI originally has the ability to function by itself, and performs an operation corresponding to its circuit configuration and outputs a desired signal when a signal in input to the LSI. For example, in the final test and initialization, a test signal for a high-speed operation can be input to conduct verification on an actual operation level.

On the contrary, in the wafer probing, the verification on the actual operation level can not be conducted because the probe does not permit the passage of the high-speed signal, but a low-speed test is conducted before the mounting from the perspective of eliminating as much waste of packaging defective products as possible.

On the other hand, in the critical path described above, it is not originally unnecessary to give delays, but a delay variation can be caused between the FFs due to the process, voltage and temperature. Between these FFs, setup and hold times have to be secured between the data and the clock, but an eye opening may close because the delay variation is caused, in which case there is caused a situation where a test result can not be obtained because the test signal does not pass through the critical path. The LSI is judged as defective when the test result can not be obtained as described above, and this is caused by the process and the like and does not necessarily mean that defective elements are present in the circuit design and configuration itself.

Here, when the LSI is judged as defective due to the process and the like, this LSI can be treated as a nondefective product and commercialized if the delay amount is adjusted during the initialization. However, it is not easy to judge whether or not the cause of the defect is the process and the like, so that even if such LSIs exist, they are all treated as defective products after the wafer probing (before the mounting), which has been the cause of a decreased yield ratio.

The present invention has been made in view of such circumstances, and is directed to provide a digital circuit, a semiconductor device and a clock adjusting method in which a low-speed general-purpose inspection apparatus is used to automatically adjust a variable delay circuit and compensate for a delay variation in order to enable an inspection and in which costs are reduced, an inspection quality is improved, and the yield ratio of products in wafer probing can be improved.

### SUMMARY OF THE INVENTION

In order to achieve this object, a digital circuit of the present invention comprises one or more clock operation circuits to which data signals are input and which output the data signals in accordance with input timing of a clock signal; and a variable delay circuit which gives a predetermined delay time to the clock signal and/or the data signals, and the digital circuit further comprises an adjusting circuit which outputs a delay setting signal whose value varies depending on whether a delay variation of the data signals output from the clock operation circuits is faster or slower than a predetermined time and which sends the delay setting signal to the variable delay circuit to set the delay time for the variable delay circuit.

When the digital circuit has such a configuration, it is judged whether the delay variation of the data signals output from the clock operation circuits is faster or slower than the predetermined time, and the delay time for the variable delay circuit is set on the basis of the result of the judgment, so that a frequency output from a low-speed general-purpose inspection apparatus can be used to judge the delay variation of the data signals.

Furthermore, whether the judged delay variation is faster or slower is reflected as variation information in the variable delay circuit, such that the variable delay circuit can be automatically adjusted to compensate for the delay time for the variable delay circuit.

Furthermore, since the general-purpose low-speed inspection apparatus can be used to achieve the compensation for the delay time for the variable delay circuit, inspection costs can be reduced.

Moreover, as it is possible to provide a clock inspection technique suitable for the low-speed general-purpose inspection apparatus, the LSI can be judged to find whether it is defective in wafer probing. As a result, the task of replacing the LSIs after mounted on a board, re-execution of initialization and wasteful packaging costs are reduced, such that an inspection quality can be improved.

Furthermore, since the delay time for the variable delay circuit is set on the basis of the delay setting signal, the delay variation of the clock operation circuits can be compensated for to ensure an eye opening and pass a test signal therethrough. Thus, it is possible to judge whether or not the LSI is good on the basis of the test signal. This can substantially eliminate a situation where the eye opening is closed due to the process and the like, and the test signal can not be detected, so that the LSI is judged as a defective product. Therefore, the LSIs having no defective elements in the circuit design and configuration itself are rarely judged as defective at the stage of the wafer probing, such that a yield ratio can be improved.

Furthermore, in the digital circuit of the present invention, the adjusting circuit comprises: a delay element which gives a predetermined delay time to a pulse signal input from the outside; and a data maintaining circuit to which an output signal of the delay element is input as a delay signal and to which the pulse signal is input, the data maintaining circuit outputting a delay setting signal indicating that the delay variation of the data signals is faster than the predetermined time when the delay signal is generated during the generation of the pulse signal, the data maintaining circuit outputting a delay setting signal indicating that the delay variation of the data signals is slower than the predetermined time when the delay signal is not generated during the generation of the pulse signal.

When the digital circuit has such a configuration, it is possible to judge whether the delay variation of the data signals is faster or slower than the predetermined time. Then, the binary result of the judgment can be set from the outside to compensate for the delay time for the variable delay circuit.

It is to be noted that a predetermined multiple includes, for example, an integral multiple (e.g., one time, two times, three times), a fractional multiple (e.g., ½ times, ⅓ times, 3/2 times) or a decimal multiple (e.g., 0.5 times, 1.5 times).

In addition, the pulse signal indicates a specific waveform of the test signal. However, the pulse signal is explained as the test signal in “DETAILED DESCRIPTION OF THE INVENTION” described later.

Furthermore, in the digital circuit of the present invention, the delay time possessed by the delay element is time corresponding to an integral multiple of the cycle of the pulse signal, or time which is the sum of the time corresponding to the integral multiple of the cycle of the pulse signal and the pulse width of the pulse signal.

When the digital circuit has such a configuration, it is possible to judge whether the delay variation of the data signals is faster or slower than the time corresponding to the integral multiple of the cycle of the test signal.

Furthermore, in the digital circuit of the present invention, the adjusting circuit comprises: a pulse signal transmission channel to which the pulse signal is input from one input terminal thereof to send the pulse signal to the data maintaining circuit; and a branch channel which branches from the input terminal or the pulse signal transmission channel to send the pulse signal to the delay element.

When the digital circuit has such a configuration, skew in the channel for transmitting the test signal can be reduced.

Furthermore, in the digital circuit of the present invention, the delay element is used as a first delay element, the adjusting circuit comprises a second delay element which gives a predetermined delay time to the pulse signal input to the data maintaining circuit, and a difference of the delay times between the first delay element and the second delay element is the integral multiple of the cycle of the pulse signal, or the sum of the integral multiple of the cycle of the pulse signal and the pulse width.

When the digital circuit has such a configuration, the difference between the delay times of the first delay element and the second delay element is the integral multiple of the cycle of the test signal or the sum of the integral multiple of the cycle of the test signal and the pulse width. Thus, the data maintaining circuit can judge whether the delay variation of the data signals is faster or slower from the result of comparing the signal output from the first delay element with the signal output from the second delay element.

Furthermore, in the digital circuit of the present invention, the adjusting circuit comprises: a plurality of delay elements which have different delay times and which give the delay times to the pulse signal input from the outside; a plurality of data maintaining circuits which are provided to correspond to the respective delay elements and to which output signals of the corresponding delay elements are input as delay signals and to which the pulse signal is input, the data maintaining circuits outputting first delay setting signals indicating that the delay variation of the data signals is faster than the predetermined time when the delay signal is generated during the generation of the pulse signal, the data maintaining circuits outputting first delay setting signals indicating that the delay variation of the data signals is slower than the predetermined time when the delay signal is not generated during the generation of the pulse signal; a plurality of latch circuits which are provided to correspond to the respective data maintaining circuits and to which the first delay setting signals from the corresponding data maintaining circuits are input and which output the first delay setting signals in accordance with input timing of a latch signal input from the outside; and a decoder which outputs a second delay setting signal on the basis of the first delay setting signals output from the respective latch circuits, and sends this second delay setting signal to the variable delay circuit to set the delay time for the variable delay circuit.

When the digital circuit has such a configuration, the delay time for the variable delay circuit can be compensated for in more detail in accordance with the number of delay elements.

For example, when the number of delay elements is three, a judgment can be made in four sections (faster than the delay time of the first delay element; slower than the delay time of the first delay element but faster than the delay time of the second delay element; slower than the delay time of the second delay element but faster than the delay time of the third delay element; slower than the delay time of the third delay element), and the delay time for the variable delay circuit can be compensated for suitably to the delay variation.

Furthermore, in the digital circuit of the present invention, the adjusting circuit comprises: a delay element which is configured to set different delay times and which gives the delay times to the pulse signal input from the outside; a data maintaining circuit to which an output signal of the delay element is input as a delay signal and to which the pulse signal is input, the data maintaining circuit outputting a first delay setting signal indicating that the delay variation of the data signals is faster than the predetermined time when the delay signal is generated during the generation of the pulse signal, the data maintaining circuit outputting a first delay setting signal indicating that the delay variation of the data signals is slower than the predetermined time when the delay signal is not generated during the generation of the pulse signal; a plurality of latch circuits which are provided to correspond to the respective delay times settable by the delay element and to which the first delay setting signal from the data maintaining circuit is input and which output the first delay setting signal in accordance with input timing of a latch signal input from the outside; and a decoder which outputs a second delay setting signal on the basis of the first delay setting signals output from the respective latch circuits, and sends this second delay setting signal to the variable delay circuit to set the delay time for the variable delay circuit.

When the digital circuit has such a configuration, the delay time for the variable delay circuit can be compensated for in more detail in accordance with the number of delay elements.

Moreover, the scale of the circuit can be significantly reduced as compared with the case where there are provided a plurality of delay elements.

Furthermore, in the digital circuit of the present invention, the adjusting circuit comprises: a rewritable or unrewritable storage device which retains one or more delay setting times set for the variable delay circuit.

When the digital circuit has such a configuration, the delay time for the variable delay circuit can be set on the basis of delay setting information retained in the storage device.

Furthermore, a semiconductor device of the present invention is a semiconductor device in which a digital circuit is installed, and the digital circuit includes a digital circuit according to any one of claims 1 to 8.

When the semiconductor device has such a configuration, a delay variation of the output signals of the digital circuit installed in the semiconductor device can be suppressed.

In particular, an adjusting circuit provided in the digital circuit judges whether the delay variation of clock signals and data signals of one semiconductor chip is faster or slower than a predetermined time, and the delay time for the variable delay circuit is compensated for on the basis of the result of the judgment, so that the delay variation can be suppressed by use of a low-speed general-purpose inspection apparatus.

Moreover, an eye opening which can be blocked by a delay variation between FFs due to the process and the like is secured in an open state, so that a low-speed test of an LSI can be conducted by a test signal which has passed through the eye opening. Therefore, the LSIs having no defective elements in the circuit design and configuration itself are judged as nondefective, such that a yield ratio in wafer probing can be improved.

Furthermore, a clock adjusting method of the present invention has the steps of: judging the state of a delay variation of data signals output from clock operation circuits in accordance with input timing of a clock signal (delay variation judging step); and setting, on the basis of the result of the judgment, a delay time of a variable delay circuit which gives a predetermined delay time to the clock signal (delay time setting step), and the clock adjusting method comprises the steps of: judging whether the delay variation of the data signals output from the clock operation circuits is faster or slower than a predetermined time (delay variation judging step); and setting the delay time for the variable delay circuit on the basis of the result of the judgment (delay time setting step).

When such a clock adjusting method is provided, it is possible to judge whether the delay variation of the data signals is faster or slower than the predetermined time, and compensate for the delay time for the variable delay circuit on the basis of the result of the judgment. Thus, the delay variation can be suppressed to secure an eye opening of the data signals, and data passing between FFs can be ensured to improve the yield ratio in the wafer probing.

As described above, according to the present invention, a digital circuit has one or more clock operation circuits, and the digital circuit comprises a variable delay circuit which gives a predetermined delay time to a clock signal, and an adjusting circuit which compensates for the delay time for the variable delay circuit. Time corresponding to a predetermined multiple of the cycle of a test signal is compared with the delay time of a delay element possessed by the adjusting circuit in order to judge whether the delay variation of data signals is faster or slower. On the basis of the result of the judgment, the delay time for the variable delay circuit is compensated for. Thus, a low-speed general-purpose inspection apparatus is used to automatically adjust the variable delay circuit and compensate for the delay variation in order to enable an inspection.

Moreover, since the low-speed general-purpose inspection apparatus is used to compensate for the delay time for the variable delay circuit, it is possible to achieve an improvement in an inspection quality as well as a reduction in cost.

Still further, since an eye opening of the data signals is secured by the compensation for the variable delay circuit, products judged as defective due to the process and the like are reduced, and thus the yield ratio in wafer probing can be improved.

### BRIEF DESCRIPTION OF THE DRAWINGS

FIG. 1 is a circuit diagram showing the configuration of a digital circuit in a first embodiment of the present invention;

FIG. 2 is a configuration diagram showing a configuration for carrying out a clock adjusting method in the first embodiment of the present invention;

FIG. 3 is a waveform chart for explaining a delay variation of data signals;

FIG. 4 is a flowchart showing a procedure of the clock adjusting method in the first embodiment of the present invention;

FIG. 5 is a timing chart showing changes over time of waveforms when the clock adjusting method in the first embodiment of the present invention is carried out;

FIG. 6 is a circuit diagram showing the configuration of a digital circuit in a second embodiment of the present invention;

FIG. 7 is a circuit diagram showing the configuration of a digital circuit in a third embodiment of the present invention;

FIG. 8 is a block diagram showing a manufacturing process of an LSI; and

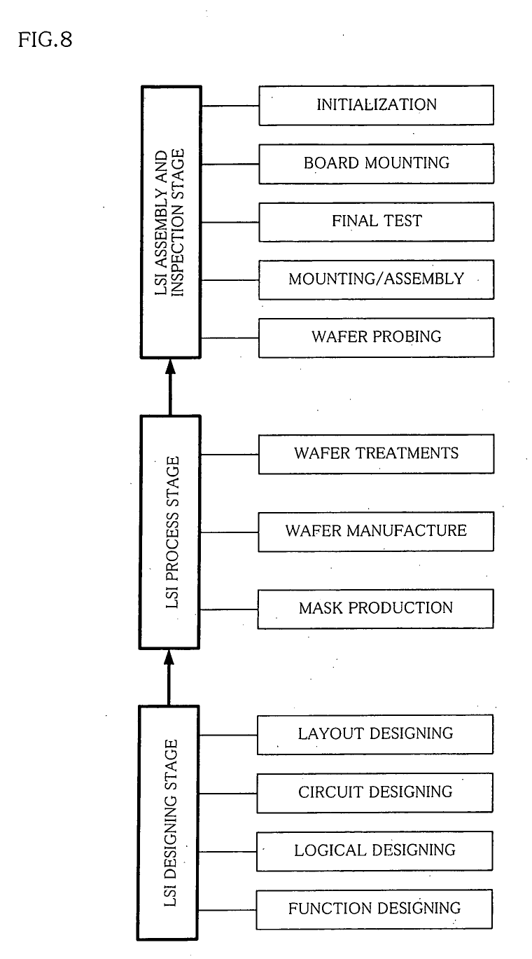

FIG. 9 is a circuit diagram showing the configuration of a conventional digital circuit which compensates for a delay variation between flip flops.

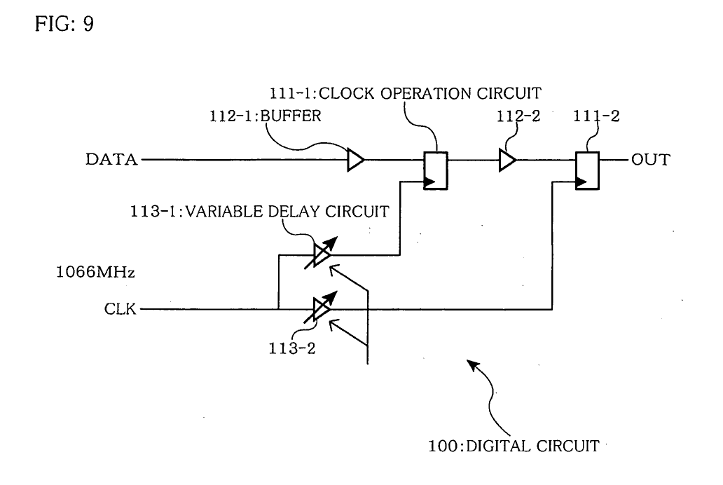

### DETAILED DESCRIPTION OF THE INVENTION

Preferred embodiments of a digital circuit, a semiconductor device and a clock adjusting method according to the present invention will hereinafter be described with reference to the drawings.

### First Embodiment

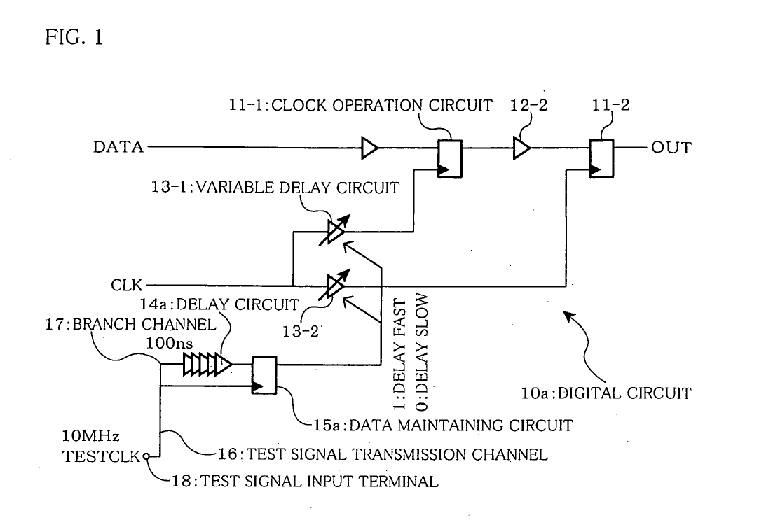

First, a first embodiment of a digital circuit, a semiconductor device and a clock adjusting method of the present invention will be described referring to FIG. 1.

FIG. 1 is a circuit diagram showing the configuration of the digital circuit in the present embodiment.

As shown in FIG. 1, a digital circuit 10a in the present embodiment has clock operation circuits 11-1 and 11-2, buffers 12-1 and 12-2, variable delay circuits 13-1 and 13-2, a delay circuit 14a, a data maintaining circuit 15a, a test signal transmission channel 16, and a branch channel 17.

The clock operation circuits 11-1 and 11-2 perform predetermined operations on the basis of the input of a clock signal.

It is to be noted that the clock operation circuits 11-1 and 11-2 in the present embodiment are circuits to which data signals are input and which output the data signals in accordance with input timing of the clock signal.

The clock operation circuits 11-1 and 11-2 can be configured by, for example, flip flop circuits or latch circuits.

The buffers 12-1 and 12-2 perform logical calculations by, for example, an AND circuit, an OR circuit and a NOT circuit during a clock cycle, and input data to the clock operation circuits. When there are a few logical calculations, the buffers may be inserted for timing adjustment. The data signals which have given delay times are input to the clock operation circuits 11-1 and 11-2.

It is to be noted that the buffers 12-1 and 12-2 are connected to a channel for transmitting the data signals in FIG. 1, but not exclusively connected to the channel for transmitting the data signals and can be connected to a channel for transmitting the clock signal.

The variable delay circuit 13-1 delays the clock signal input to the clock operation circuit 11-1. On the other hand, the variable delay circuit 13-2 delays the clock signal input to the clock operation circuit 11-2.

The variable delay circuits 13-1 and 13-2 permit the delay times thereof to be set on the basis of signals from the outside. The delay times can be set, for example, by giving digital data signals or by analog control in accordance with a current amount.

In the variable delay circuits 13-1 and 13-2 of the present embodiment, delays are set by delay setting signals from an adjusting circuit (the delay circuit 14a and the data maintaining circuit 15a). A specific operation for setting the delays by the adjusting circuit will be described later in detail in “the operation of the digital circuit in the present embodiment and delay setting for the variable delay circuits”.

The delay circuit (delay element) 14a gives a predetermined delay time to a TESTCLK (test signal) input from the outside (e.g., a low-speed general-purpose inspection apparatus 20 (hereinafter referred to as an inspection apparatus 20 for short)), and then sends it to the data maintaining circuit 15a.

In the present embodiment, this delay circuit 14a can have a cycle corresponding to the frequency of an output signal (test signal) of the inspection apparatus 20 as the delay time. For example, when the maximum output frequency of the inspection apparatus 20 is 10 MHz, a cycle of 100 ns thereof is used as the delay time of the delay circuit 14a.

Furthermore, the delay circuit 14a can have, as the delay time, time corresponding to a predetermined multiple of the cycle equivalent to the frequency of the output signal of the inspection apparatus 20. Here, the predetermined multiple can be, for example, two times, three times, four times, ½ times or 3/2 times. Further, for example, the delay time of the delay circuit 14a can be 200 ns (two times), 300 ns (three times), 400 ns (four times), 50 ns (½ times) or 150 ns ( 3/2 times) when the maximum output frequency of the inspection apparatus 20 is 10 MHz.

Furthermore, the delay circuit 14a can have, as the delay time, the sum of the time corresponding to a predetermined multiple of the cycle corresponding to the frequency of the output signal of the inspection apparatus 20, and a pulse width of that output signal. For example, when the maximum output frequency of the inspection apparatus 20 is 10 MHz, its cycle is 100 ns, and its pulse width is 50 ns. Thus, if the predetermined multiple is one time, the delay time of the delay circuit 14a is 150 ns.

It is to be noted that the delay circuit 14a is connected to a data input terminal of the data maintaining circuit 15a in FIG. 1, but the delay circuit 14a is not exclusively connected to the data input terminal of the data maintaining circuit 15a and may be connected to a clock input terminal thereof. That is, the delay circuit 14a can be connected to one or both of the data input terminal and the clock input terminal of the data maintaining circuit 15a.

Furthermore, when the delay circuits 14a are connected to both of the data input terminal and the clock input terminal of the data maintaining circuit 15a, a difference of the delay times between these delay circuits 14a can be an integral multiple of the frequency input from the inspection apparatus 20 or the sum of the integral multiple and the pulse width.

In the data maintaining circuit 15a, a signal from the delay circuit 14a (TESTCLK to which a predetermined delay time has been given, a delay signal) is input at the clock input terminal, and the TESTCLK is input at the clock input terminal. Then, the delay setting signal is output in accordance with input timing of the TESTCLK.

Thus, the data maintaining circuit 15a can output the delay setting signal on the basis of the delay signal and the test signal from the delay circuit 14a.

The delay setting signal output from the data maintaining circuit 15a is sent to the variable delay circuits 13-1 and 13-2. Thus, the delay times are set in the variable delay circuits 13-1 and 13-2.

The generation of the delay setting signal in the data maintaining circuit 15a will be described in detail later in “the operation of the digital circuit in the present embodiment and delay setting for the variable delay circuits”.

It is to be noted that the data maintaining circuit 15a can be configured by, for example, a flip flop or a latch circuit.

Moreover, in the present embodiment, the delay circuit 14a and the data maintaining circuit 15a are generically called an “adjusting circuit”.

Furthermore, the whole digital circuit 10a including the adjusting circuit shown in FIG. 1 is installed in the same LSI. A process, temperature and voltage which are the causes of a delay variation of the data signals output from the clock operation circuits 11-1 and 11-2 can also be the causes of a delay variation of the delay signals output from the delay circuits 14a of the adjusting circuit. Thus, it is possible to consider that judging in the data maintaining circuit 15a whether the generation timing of the delay signals of the delay circuits 14a is faster or slower than the time corresponding to the integral multiple of the cycle of the TESTCLK is equivalent to the delay variation of the data signals output from the clock operation circuits 11-1 and 11-2.

In the test signal transmission channel 16, the TESTCLK sent from the outside (e.g., the inspection apparatus 20) is input from one input end (test signal input terminal 18), and then the TESTCLK is sent to the data maintaining circuit 15a.

The branch channel 17 branches from its input terminal or the test signal transmission channel 16 to send the TESTCLK to the delay circuits 14a.

When the test signal transmission channel 16 and the branch channel 17 are configured in this manner, the channel for sending the TESTCLK to the data maintaining circuit 15a and the channel for sending the TESTCLK to the delay circuits 14a are the same partway, so that skew can be reduced as compared with the case where these channels are separately and independently provided.

It is to be noted that the digital circuit 10a of the present embodiment comprises a rewritable or unrewritable storage device (not shown) which retains, as delay setting information, one or more delay settings for the variable delay circuits 13-1 and 13-2.

This storage device can be configured by, for example, a register (rewritable), a mask ROM (unrewritable) or fuse (unrewritable after set in an inspection step).

When this storage device is provided, the delay times of the variable delay circuits 13-1 and 13-2 can be set on the basis of the delay setting information retained in the storage device.

When the digital circuit has the configuration as described above, the variable delay circuits can be adjusted and set only by the delay setting carried out by the adjusting circuit, so that it is possible to reflect the delay variation and increase timing margins during an inspection only by the addition of a circuit on a delay setting side without modifying the channel of the DATA/CLK main line.

However, if the variable delay circuits 13-1 and 13-2 are not suitably set when the operations of the clock operation circuits 11-1 and 11-2 are to be inspected in wafer probing or in a final test without the adjusting circuit, the output data of the clock operation circuit 11-2 causes a cycle lag per chip with respect to the input data of the clock operation circuit 11-1, or loss of data occurs. The reason is that the digital circuit shown in FIG. 1 can not operate the variable delay circuits in a fixed state for all variation states.

However, since a pattern given from the general-purpose inspection apparatus is a fixed pattern, the variation state can not be detected to set delays in the variable delay circuits 13-1 and 13-2. Thus, instead of setting the delays from the inspection pattern, delay information (fast or slow) is given from the adjusting circuit to set the clock operation circuits 11-1 and 11-2 to always operate with the same cycle. This enables an operation with the fixed pattern.

Next, a configuration for carrying out the clock adjusting method in the present embodiment will be described.

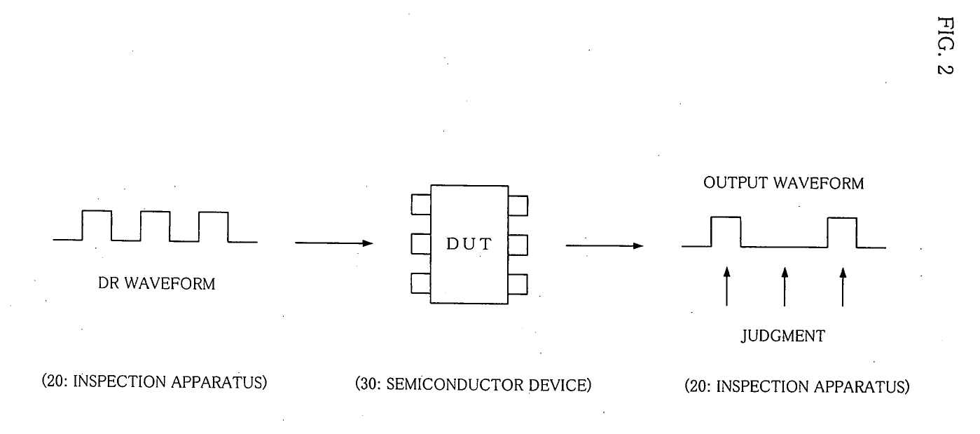

First, a general configuration for conducting the wafer probing will be described referring to FIG. 2.

In conducting the wafer probing, the inspection apparatus 20 and a semiconductor device (DUT) 30 are prepared, as shown in FIG. 2.

The inspection apparatus 20 is a low-speed general-purpose inspection apparatus, and sends a DR signal (DR (DRIVER) waveform) to the DUT 30 to inspect whether or not the electric properties of the digital circuit installed in the DUT 30 are good.

The digital circuit having a plurality of clock operation circuits is installed in the DUT 30.

Furthermore, a DATA signal and CLK signal (DR waveform) are input with predetermined timing from the inspection apparatus 20 to an DATA input and a CLK input of the digital circuit 10a installed in the DUT 30. An output signal is then output from the digital circuit 10a.

The output signal from the DUT 30 is input to the inspection apparatus 20, and the inspection apparatus 20 judges whether the electric properties of the digital circuit installed in the DUT 30 are good on the basis of a signal waveform (output waveform) of the output signal.

Here, the delay variation of the data signals is large and a sufficient eye opening can not be secured, such that a trouble is caused in data passing in the clock operation circuits 11-1 and 11-2, and this makes it impossible to obtain a data signal necessary for judging whether or not the DUT 30 is good, in which case it is necessary to decrease the delay variation to increase the timing margins.

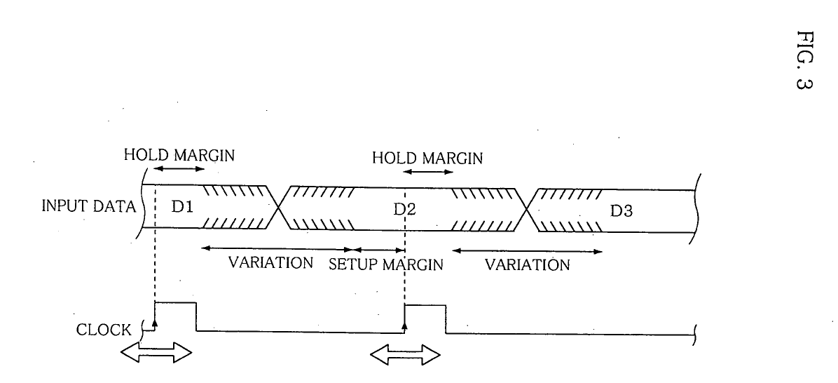

That is, it is necessary to secure constant and sufficient setup margins and hold margins for the data signals as shown in FIG. 3, but if the delay variation is larger, these setup margins and others can not be sufficiently secured, and the data passing between the clock operation circuits 11-1 and 11-2 becomes impossible.

Thus, the digital circuit having the adjusting circuit as shown in FIG. 1 is installed in the semiconductor device 30, such that the delay times of the variable delay circuits 13-1 and 13-2 are set to compensate for the delay variation of the data signals.

That is, the TESTCLK is input by the configuration shown in FIG. 2 from the inspection apparatus 20 to the test signal input terminal 18 in the digital circuit 10a installed in the semiconductor device 30. Then, by the procedure described in the next “the clock adjusting method of the digital circuit in the present embodiment”, the delay times of the variable delay circuits 13-1 and 13-2 are set to compensate for the delay variation of the data signals.

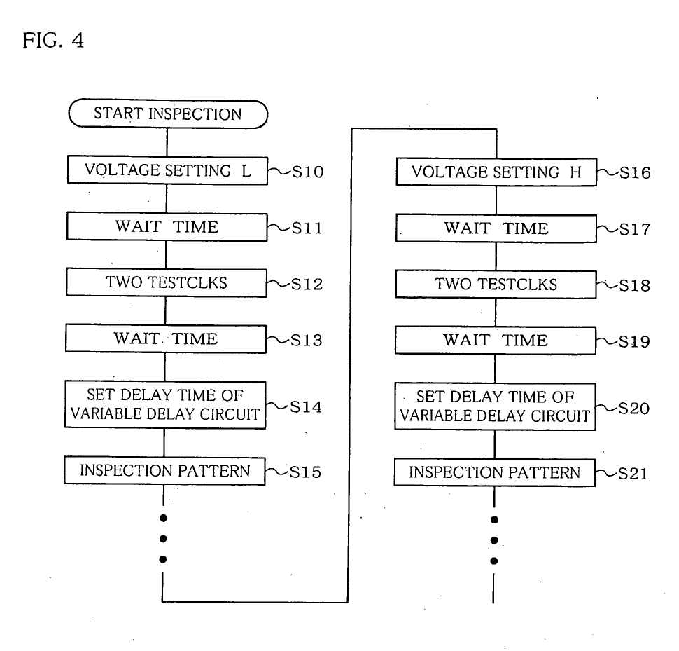

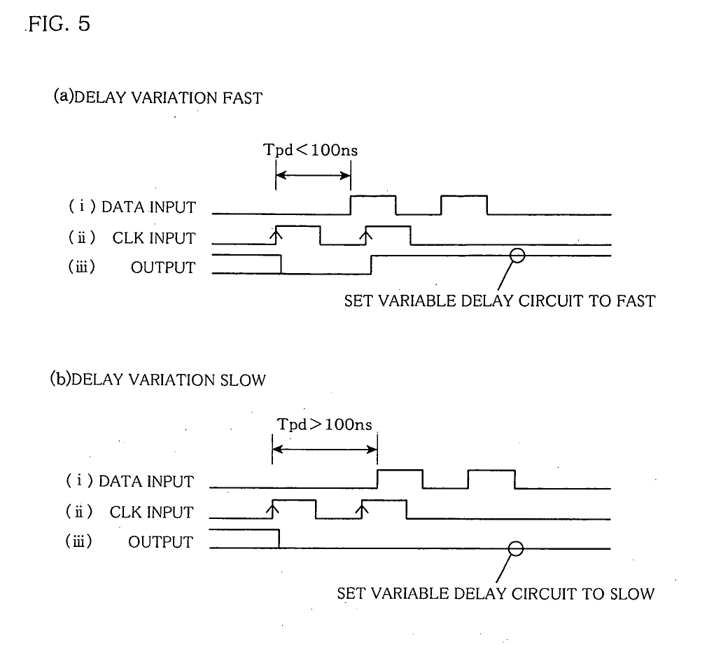

Next, the clock adjusting method of the digital circuit in the present embodiment will be described referring to FIGS. 4 and 5.

FIG. 4 is a flowchart showing a procedure of the clock adjusting method. FIG. 5 is a waveform chart showing waveforms of signals (a data input signal of the data maintaining circuit 15a (DATA input), a clock input signal of the data maintaining circuit 15a (CLK input), and an output signal of the data maintaining circuit 15a (output)) obtained when the clock adjusting method is carried out.

It is to be noted that the delay variation of the data signals is caused by the influence of the process, temperature and voltage. Therefore, it is desirable to inspect a plurality of temperatures and voltages to suitably set the delay times of the variable delay circuits 13-1 and 13-2.

For example, when the voltage set in the digital circuit 10a is 5 V, inspections are conducted, for example, for the cases of 4.5 V and 5.5 V. In this manner, the eye opening for the data signals are secured within a range of 4.5 V to 5.5 V even when the delay variation is caused by a voltage change, and the inspection for the wafer probing is possible.

Thus, in the present embodiment, a voltage setting L and a voltage setting H are inspected.

First, the voltage setting L is inspected.

When the voltage setting L is set (step 10), two TESTCLKs are input from the inspection apparatus 20 to the test signal input terminal 18 (step 12) after WAIT TIME (step 11).

In WAIT TIME (step 13), a predetermined delay time is given to the TESTCLK by the delay circuit 14a, and the TESTCLK is sent to the data maintaining circuit 15a as the delay signal. In the data maintaining circuit 15a, the TESTCLK is input (CLK input, FIG. 5(a)(ii), (b)(ii)), and the delay signal is input from the delay circuit 14a (DATA input, FIG. 5(a)(i), (b)(i)), and on the basis of the result of comparing the TESTCLK with the delay signal, the delay setting signal is output (output, FIG. 5(a)(iii), (b)(iii)) and then sent to the variable delay circuits 13-1 and 13-2 (delay variation judging step). In response to this delay setting signal, the delay times of the variable delay circuits 13-1 and 13-2 are set (delay variation judging step, step 14).

Then, the inspection pattern is given to the DUT 30 to inspect the DUT 30 (step 15).

Subsequently, the voltage setting H is inspected. Since the delay variation in the voltage setting H is different from that in the voltage setting L, the adjusting circuit needs to be reset.

When the voltage setting H is set (step 16), the inspection is conducted in the procedure similar to the procedure for the inspection of the voltage setting L (step 17 to step 21). Thus, the delay times of the variable delay circuits 13-1 and 13-2 are set.

By such a procedure, suitable delay times are set in the variable delay circuits 13-1 and 13-2.

Next, the operation of the digital circuit of the present invention and the delay setting for the variable delay circuits will be described referring to FIG. 5.

First, a case where the delay variation is FAST will be described referring to FIG. 5(a).

As shown in FIG. 5(a), the waveforms of the DATA input, the CLK input and the output in the data maintaining circuit 15a are observed.

For example, when the CLK input has a cycle of 100 ns, a time difference Tpd between the DATA input and the CLK input is smaller than 100 ns (Tpd<100 ns, FIG. 5(a)(i), (ii)), in which case the DATA input is input at the rising edge of the CLK input, so that a signal (signal indicating “1”) as shown by FIG. 5(a)(iii) is output from the output of the digital circuit 10a.

At this point, “delay FAST” is set in the variable delay circuits 13-1 and 13-2 (FIG. 5(a), FIG. 1 “1:delay FAST”).

Next, a case where the delay variation is SLOW will be described referring to FIG. 5(b).

As shown in FIG. 5(b), the waveforms of the data input (DATA input), the clock input (CLK input) and the output in the data maintaining circuit 15a are observed.

For example, when the CLK signal has a cycle of 100 ns, the time difference Tpd between the DATA signal and the CLK signal is greater than 100 ns (Tpd>100 ns, FIG. 5(b)(i), (ii)), in which case the DATA signal is not input at the rising edge of the CLK signal, so that no signal is output from the output OUT of the digital circuit (FIG. 5(b)(iii), a signal indicating “0” is output).

At this point, “delay SLOW” is set in the variable delay circuits 13-1 and 13-2 (FIG. 5(b), FIG. 1 “2:delay SLOW”).

When the digital circuit in the present embodiment executes such an operation, two kinds of delay settings for FAST and SLOW can be made for the variable delay circuits.

According to such a method, it is only necessary to be able to make a setting for either FAST or SLOW, such that setting time can be reduced.

It is to be noted that the following three approaches are conceivable to find whether the delay is fast or slow.

The first approach is to find by the frequency input from the inspection apparatus 20.

The second approach is to regard, as the delay time of the delay circuit 14a, the delay time corresponding to an integral multiple of the cycle of the signal (TESTCLK) input from the inspection apparatus 20, and compare the delay time of the delay circuit 14a with the integral multiple of the cycle of the signal (TESTCLK) input from the inspection apparatus 20.

The third approach is to regard, as the delay time of the delay circuit 14a, the delay time which is the sum of the integral multiple of the frequency of the signal (TESTCLK) input from the inspection apparatus 20 and the pulse width of the input signal, and compare the delay time of the delay circuit 14a with a multiple of the cycle of the signal (TESTCLK) input from the inspection apparatus 20 and with the pulse width thereof.

Furthermore, in the data maintaining circuit 15a, the delay variation judgment may be different in accordance with the comparison depending on whether the delay variation is the fastest or slowest.

That is, it is possible to judge that the delay variation of the data signals is faster than a predetermined time when the delay variation is the fastest, and judge that the delay variation is slower than the predetermined time when the delay variation is the slowest. In this case, the delay time for the variable delay circuit can also be compensated for on the basis of the result of the judgment.

Furthermore, in the data maintaining circuit 15a, it is possible to detect the state of the delay variation which is judged differently in accordance with the comparison when the delay variation continuously changes from the fastest to the slowest.

That is, in the case where the delay variation of the data signals continuously changes from the fastest to the slowest, it is possible to judge that the delay variation is faster than the predetermined time when the delay variation is close to the fastest, and judge that the delay variation is slower than the predetermined time when the delay variation is close to the slowest. In this case, the delay time for the variable delay circuit can also be compensated for on the basis of the result of the judgment.

According to the digital circuit, the semiconductor device and the clock adjusting method described above, it is possible to judge whether the delay variation of the data signals is faster or slower than the predetermined time, and compensate for the delay time for the variable delay circuit on the basis of the result of the judgment.

Therefore, it is possible to provide a clock adjusting method suitable for the low-speed general-purpose inspection apparatus. In this manner, since the clock operation circuits can be inspected before the mounting, wasteful packaging and mounting can be prevented, and it is possible to judge whether the LSI is defective in the wafer probing, so that the wasteful packaging can be prevented, and an inspection quality can be improved.

Moreover, the eye opening which can be blocked due to the process and the like is secured by compensating for the delay amount of the variable delay circuits, and the test signal can be passed therethrough. Thus, it is possible to judge, as nondefective, the LSI which has no problem in circuit design and configuration but has been judged as defective due to the process and the like, and the LSI can be shipped as a product after initialization. Therefore, a yield ratio in the wafer probing can be improved.

### Second Embodiment

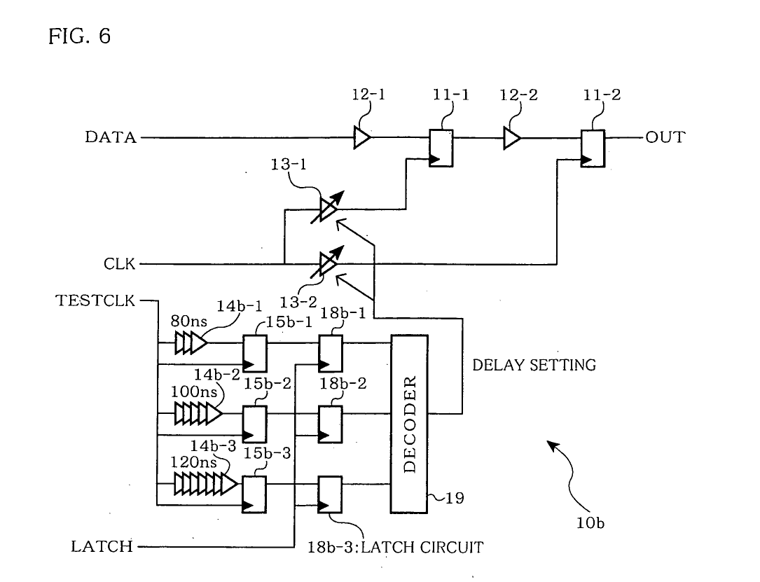

Next, a second embodiment of a digital circuit, a semiconductor device and a clock adjusting method of the present invention will be described referring to FIG. 6.

FIG. 6 is a circuit diagram showing the configuration of the digital circuit in the present embodiment.

The present embodiment is different from the first embodiment in that there are provided a plurality of delay circuits, data maintaining circuits and latch circuits so that a judgment on a delay variation and the compensation for a delay time can be achieved in more detail.

Therefore, in FIG. 6, the same numerals are assigned to the same component parts as those in FIG. 1, and they are not described in detail.

As shown in FIG. 6, a digital circuit 10b in the present embodiment has clock operation circuits 11-1 and 11-2, buffers 12-1 and 12-2, variable delay circuits 13-1 and 13-2, delay circuits 14b-1 to 14b-3, flip flops 15b-1 to 15b-3, latch circuits 18b-1 to 18b-3, and a decoder (DECODER) 19.

Here, the delay circuits 14b-1 to 14b-3 have different delay times. For example, as shown in FIG. 6, the delay times can be 80 ns in the first delay circuit 14b-1, 100 ns in the second delay circuit 14b-2, and 120 ns in the third delay circuit 14b-3.

It is to be noted that the three delay circuits 14b are provided in the configuration in the present embodiment, but the number of delay circuits 14b is not limited to three, and may be two or four or more.

The flip flops 15b-1 to 15b-3 are provided to correspond to the delay circuits 14b-1 to 14b-3, respectively. Output signals of the corresponding delay circuits 14b-1 to 14b-3 are input to the flip flops 15b-1 to 15b-3 as delay signals, and the flip flops 15b-1 to 15b-3 output the delay signals in accordance with input timing of a test signal.

As the flip flops 15b-1 to 15b-3 are provided one to one for the delay circuits 14b-1 to 14b-3, the number of flip flops 15b-1 to 15b-3 is the same as the number of delay circuits 14b-1 to 14b-3.

The latch circuits 18b-1 to 18b-3 are provided to correspond to the flip flops 15b-1 to 15b-3, respectively. Output signals of the corresponding flip flops 15b-1 to 15b-3 are input to the latch circuits 18b-1 to 18b-3 as delay signals, and the latch circuits 18b-1 to 18b-3 output the delay signals in accordance with input timing of a LATCH signal.

As the latch circuits 18b-1 to 18b-3 are provided one to one for the flip flops 15b-1 to 15b-3 (or the delay circuits 14b-1 to 14b-3), the number of latch circuits 18b-1 to 18b-3 is the same as the number of flip flops 15b-1 to 15b-3 (or the delay circuits 14b-1 to 14b-3).

The latch circuits 18b-1 to 18b-3 are provided when the TESTCLK is continuously input.

In the first embodiment, two TESTCLKs are input, as shown in FIG. 5. Thus, the correspondence between the waveforms of the DATA input and the CLK input is clear.

On the contrary, in the present embodiment, the TESTCLK is continuously input, and it is therefore necessary to fix the waveforms in the latch circuits. This makes it clear the correspondence between the waveforms of the DATA input and the CLK input, and a time difference between them can be obtained.

Output signals from the latch circuits 18b-1 to 18b-3 are input to the decoder 19, and the decoder 19 carries out the delay setting for the variable delay circuits 13-1 and 13-2 on the basis of the output signals.

In the present embodiment, since there are provided the three delay circuits 14b-1 to 14b-3, this delay setting can be set on four levels:

(1) setting when the delay variation of data signals is faster than the first delay circuit 14b-1; (2) setting when the delay variation of the data signals is slower than the first delay circuit 14b-1 but faster than the second delay circuit 14b-2; (3) setting when the delay variation of the data signals is slower than the second delay circuit 14b-2 but faster than the third delay circuit 14b-3; and (4) setting when the delay variation of the data signals is slower than the third delay circuit 14b-3.

Thus, it is possible to carry out the delay setting suitable to the variable delay circuits 13-1 and 13-2 depending on the degree of the delay variation.

It is to be noted that the digital circuit 10b in the present embodiment can be installed in a semiconductor device 30 in the same manner as the digital circuit 10a in the first embodiment.

Moreover, the clock adjusting method which is carried out in the configuration shown in FIG. 2 using the digital circuit 10b in the present embodiment can be carried out with the same steps (steps shown in FIG. 4) as in the clock adjusting method in the first embodiment, and results similar to those in FIG. 5 can be obtained. Therefore, in the present embodiment, it is also possible, in the adjusting circuit, to judge whether the delay variation of the data signals is faster or slower than a predetermined time, compensate for the delay times of the variable delay circuits 13-1 and 13-2 on the basis of the result of the judgment, and suppress the delay variation.

As described above, according to the digital circuit, the semiconductor device and the clock adjusting method in the present embodiment, defective LSI products can be detected in wafer probing by a simple configuration with the adjusting circuit and others in accordance with a technique suitable for a low-speed general-purpose inspection apparatus, so that costs can be lower than in conventional clock adjusting methods, and an inspection quality and a yield ratio can be improved.

### Third Embodiment

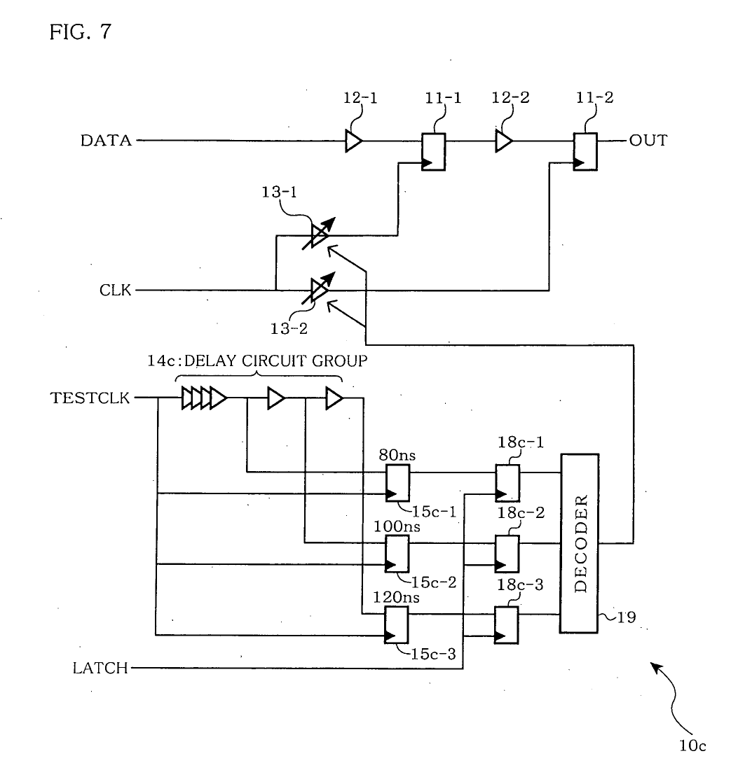

Next, a third embodiment of a digital circuit, a semiconductor device and a clock adjusting method of the present invention will be described referring to FIG. 7.

FIG. 7 is a circuit diagram showing the configuration of the digital circuit in the present embodiment.

The present embodiment is different from the first embodiment in the configuration of an adjusting circuit. That is, in the configuration of the first embodiment, the adjusting circuit has a delay circuit with a predetermined delay time, and one data maintaining circuit to which a signal output from the delay circuit is input and which outputs the signal in accordance with input timing of a test signal. However, in the configuration of the present embodiment, the adjusting circuit comprises a plurality of data maintaining circuits and a plurality of latch circuits, and each of the data maintaining circuits picks out a predetermined delay time from the group of delay circuits to input a delayed test signal therein. Other components are similar to those in the first embodiment.

Therefore, in FIG. 7, the same numerals are assigned to the same component parts as those in FIG. 1, and they are not described in detail.

As shown in FIG. 7, a digital circuit 10c in the present embodiment has clock operation circuits 11-1 and 11-2, buffers 12-1 and 12-2, variable delay circuits 13-1 and 13-2, a delay circuit group 14c, data maintaining circuits 15c-1 to 15c-3, latch circuits 18c-1 to 18c-3, and a decoder (DECODER) 19.

Here, the delay circuit group 14c can have, for example, a configuration in which delay circuits are cascade-connected. Thus, it is possible to obtain a delay time corresponding to the position where it is picked out. For example, as shown in FIG. 7, delay times 80 ns (first setting), 100 ns (second setting) and 120 ns (third setting) can be obtained in accordance with the pick-out positions thereof.

Signals to which the delay times corresponding to the pick-out positions in the delay circuit group 14c are given are input as delay signals to the data maintaining circuits 15c-1 to 15c-3, and the data maintaining circuits 15c-1 to 15c-3 output the delay signals in accordance with input timing of a test signal.

For example, a delay signal to which the delay time 80 ns is given is input to the data maintaining circuit 15c-1, a delay signal to which the delay time 100 ns is given is input to the data maintaining circuit 15c-2, and a delay signal to which the delay time 120 ns is given is input to the data maintaining circuit 15c-3.

The delay signals from the data maintaining circuits 15c-1 to 15c-3 are input to the latch circuits 18c-1 to 18c-3, and the latch circuits 18c-1 to 18c-3 output the delay signals in accordance with input timing of a LATCH signal.

Output signals from the latch circuits 18c-1 to 18c-3 are input to the decoder 19, and the decoder 19 carries out the delay setting for the variable delay circuits 13-1 and 13-2 on the basis of the output signals.

In the present embodiment, since the delay time of the delay circuit group 14c can be set at the three levels, this delay setting can be made on four levels:

(1) setting when the delay variation of data signals is faster than the first setting; (2) setting when the delay variation of the data signals is slower than the first setting but faster than the second setting; (3) setting when the delay variation of the data signals is slower than the second setting but faster than the third setting; and (4) setting when the delay variation of the data signals is slower than the third setting.

Thus, it is possible to carry out the delay setting suitable to the variable delay circuits 13-1 and 13-2 depending on the degree of the delay variation.

It is to be noted that the digital circuit 10c in the present embodiment can be installed in a semiconductor device 30 in the same manner as the digital circuit 10a in the first embodiment.

Moreover, the clock adjusting method which is carried out in the configuration shown in FIG. 2 using the digital circuit 10c in the present embodiment can be carried out with the same steps (steps shown in FIG. 4) as in the clock adjusting method in the first embodiment, and results similar to those in FIG. 5 can be obtained. Therefore, in the present embodiment, it is also possible, in the adjusting circuit, to judge whether the delay variation of the data signals is faster or slower than a predetermined time, compensate for the delay times of the variable delay circuits 13-1 and 13-2 on the basis of the result of the judgment, and suppress the delay variation.

As described above, according to the digital circuit, the semiconductor device and the clock adjusting method in the present embodiment, defective LSI products can be detected in wafer probing by a simple configuration with the adjusting circuit and others in accordance with a technique suitable for a low-speed general-purpose inspection apparatus, so that costs can be lower than in conventional clock adjusting methods, and an inspection quality can be improved.

Moreover, since an eye opening of the data signals is secured by compensating for the delay amount of the variable delay circuits, products judged as defective due to a process and the like are reduced, and thus the yield ratio in the wafer probing can be improved.

While the preferred embodiments of the digital circuit, the semiconductor device and the clock adjusting method of the present invention have been described above, the digital circuit, the semiconductor device and the clock adjusting method according to the present invention are not exclusively limited to the embodiments described above, and it should be understood that various modifications can be made within the scope of the present invention.

For example, in the embodiments described above, the frequency of the TESTCLK of the low-speed general-purpose inspection apparatus is 10 MHz, and the delay time of the delay circuit 14 is 100 ns (further, 80 ns, 120 ns). However, the delay time of the delay circuit 14 is not limited to 100 ns or the like, and can be a predetermined multiple of the cycle of the test signal (e.g., 50 ns, 150 ns, 200 ns).

Furthermore, there are provided two clock operation circuits, two buffers and two variable delay circuits in the configuration of each of the embodiments, but the number of clock operation circuits and others is not limited to two, and they may be provided in any number. In this case, the delay setting by the adjusting circuit is carried out for each of the variable delay circuits.

Still further, the present invention provides an inspection technique suitable to the low-speed general-purpose inspection apparatus used in the wafer probing, but it is not limited to the wafer probing and can be carried out in the final test.

It is to be noted that the digital circuit, the semiconductor device and the clock adjusting method of the present invention may be any combination of the digital circuit, the semiconductor device and the clock adjusting method in the first, second and third embodiments.

The present invention is an invention for compensating for a delay variation between clock operation circuits of a digital circuit installed in an LSI, and can therefore be utilized for an inspection apparatus and a clock adjusting method for compensating for the delay variation between the clock operation circuits.

What is claimed is:

1. A digital circuit comprising:
one or more clock operation circuits to which data signals are input and which output the data signals in accordance with input timing of a clock signal; and
a variable delay circuit which gives a predetermined delay time to the clock signal and/or the data signals,
the digital circuit further comprising an adjusting circuit which outputs a delay setting signal whose value varies depending on whether a delay variation of the data signals output from the clock operation circuits is faster or slower than a predetermined time and which sends the delay setting signal to the variable delay circuit to set the delay time for the variable delay circuit to a different time.

2. The digital circuit according to claim 1, wherein the adjusting circuit comprises:
a delay element which gives a predetermined delay time to a pulse signal input from the outside; and
a data maintaining circuit to which an output signal of the delay element is input as a delay signal and to which the pulse signal is input, the data maintaining circuit outputting a delay setting signal indicating that the delay variation of the data signals is faster than the predetermined time when the delay signal is generated during the generation of the pulse signal in another cycle, the data maintaining circuit outputting a delay setting signal indicating that the delay variation of the data signals is slower than the predetermined time when the delay signal is not generated during the generation of the pulse signal in another cycle.

3. The digital circuit according to claim 2, wherein the delay time possessed by the delay element is
time corresponding to an integral multiple of the cycle of the pulse signal, or time which is the sum of the time corresponding to the integral multiple of the cycle of the pulse signal and the pulse width of the pulse signal.

4. The digital circuit according to claim 2, wherein the adjusting circuit comprises:
a pulse signal transmission channel to which the pulse signal is input from one input terminal thereof to send the pulse signal to the data maintaining circuit; and
a branch channel which branches from the input terminal or the pulse signal transmission channel to send the pulse signal to the delay element.

5. The digital circuit according to any one of claims 2, wherein
the delay element is used as a first delay element,
the adjusting circuit comprises a second delay element which gives a predetermined delay time to the pulse signal input to the data maintaining circuit, and
a difference of the delay times between the first delay element and the second delay element is the integral multiple of the cycle of the pulse signal, or the sum of the integral multiple of the cycle of the pulse signal and the pulse width.

6. The digital circuit according to claim 1, wherein the adjusting circuit comprises:
a plurality of delay elements which have different delay times and which give the delay times to the pulse signal input from the outside;
a plurality of data maintaining circuits which are provided to correspond to the respective delay elements and to which output signals of the corresponding delay elements are input as delay signals and to which the pulse signal is input, the data maintaining circuits outputting first delay setting signals indicating that the delay variation of the data signals is faster than the predetermined time when the delay signal is generated during the generation of the pulse signal, the data maintaining circuits outputting first delay setting signals indicating that the delay variation of the data signals is slower than the predetermined time when the delay signal is not generated during the generation of the pulse signal;
a plurality of latch circuits which are provided to correspond to the respective data maintaining circuits and to which the first delay setting signals from the corresponding data maintaining circuits are input and which output the first delay setting signals in accordance with input timing of a latch signal input from the outside; and
a decoder which outputs a second delay setting signal on the basis of the first delay setting signals output from the respective latch circuits, and sends this second delay setting signal to the variable delay circuit to set the delay time for the variable delay circuit.

7. The digital circuit according to claim 1, wherein the adjusting circuit comprises:
a delay element which is configured to set different delay times and which gives the delay times to the pulse signal input from the outside;
a data maintaining circuit to which an output signal of the delay element is input as a delay signal and to which the pulse signal is input, the data maintaining circuit outputting a first delay setting signal indicating that the delay variation of the data signals is faster than the predetermined time when the delay signal is generated during the generation of the pulse signal, the data maintaining circuit outputting a first delay setting signal indicating that the delay variation of the data signals is slower than the predetermined time when the delay signal is not generated during the generation of the pulse signal;
a plurality of latch circuits which are provided to correspond to the respective delay times settable by the delay element and to which the first delay setting signal from the data maintaining circuit is input and which output the first delay setting signal in accordance with input timing of a latch signal input from the outside; and
a decoder which outputs a second delay setting signal on the basis of the first delay setting signals output from the respective latch circuits, and sends this second delay setting signal to the variable delay circuit to set the delay time for the variable delay circuit.

8. The digital circuit according to any one of claims 1, wherein the adjusting circuit comprises:
a rewritable or unrewritable storage device which retains one or more delay setting times set for the variable delay circuit.

9. A semiconductor device in which a digital circuit is installed, wherein
the digital circuit includes a digital circuit according to any one of claims 1.

10. A clock adjusting method which has the steps of: judging the state of a delay variation of data signals output from clock operation circuits in accordance with input timing of a clock signal; and setting, on the basis of the result of the judgment, a delay time of a variable delay circuit which gives a predetermined delay time to the clock signal, the clock adjusting method comprising the steps of:
judging whether the delay variation of the data signals output from the clock operation circuits is faster or slower than a predetermined time; and
setting the delay time for the variable delay circuit on the basis of the result of the judgment.
